(19) United States
(12) Patent Application Publication
(10) Pub. No.: US 2013/0078552 A1
(43) Pub. Date: Mar. 28, 2013

(54) Dedicated Mask and Production Method thereof, LCD Panel Production Method

(71) Applicants: Kuancheng Lee, Shenzhen (CN); Chunliang Lee, Shenzhen (CN)

(72) Inventors: Kuancheng Lee, Shenzhen (CN); Chunliang Lee, Shenzhen (CN)

(21) Appl. No.: 13/322,545

(22) PCT Filed: Oct. 14, 2011
(86) PCT No.: PCT/CN2011/080819

§ 371 Date: Nov. 25, 2011

(30) Foreign Application Priority Data
Sep. 28, 2011 (CN) 201110302101.0

(51) Int. Cl. G03F 7/20; G03F 1/42; G03F 1/68; G03F 1/00

(52) U.S. Cl. 430/5; 430/320; 430/7

(57) ABSTRACT

The present invention discloses a dedicated mask, a production method thereof, and a production method of a liquid crystal display (LCD) panel. The production method of an LCD panel comprises the following steps: coating a sealant around display areas of the LCD panel; laying a mask used for producing the LCD panel on the LCD panel, wherein the shape of a shading film of the mask used for producing the LCD panel is consistent with the shape of the display areas formed by the sealant; arranging the shading film in the position corresponding to an upper part of the display areas; and irradiating the sealant of the LCD panel exposed outside the shading film using a light source. The present invention can reduce the production cost, enhance the cost reduction, and effectively prevents the disturbance from a light source.

### TECHNICAL FIELD

The present invention relates to the field of liquid crystal displays (LCDs), and more particularly to a dedicated mask, a production method thereof as well as an LCD panel production method.

### BACKGROUND

In the process of production of an LCD panel, a sealant is coated on a large base plate to form a plurality of display areas. In the increasingly mature processes for producing LCD panels, ultraviolet (UV) irradiation plays an important role in the cell process of the sealant for maintaining and implementing of sealant integrity required for LCDs. However, conventional irradiation cell processes using a light source influence other structures of LCDs and frequently cause optical errors, or produce mura having different shapes on the LCDs, thereby worsening the display effect.

### SUMMARY

One objective of the present invention is to provide a mask and a production method thereof and an LCD panel production method used for producing an LCD panel capable of improving the display effect of an LCD.

The objective of the present invention is achieved by the following technical schemes.

A mask used for producing an LCD panel, comprises a translucent panel, and the translucent panel is covered with a shading film, the shape of the shading film is consistent with the shape of display areas formed by a sealant coated on the LCD panel.

Preferably, the translucent panel is further provided with aligning marks used for realizing the accurate alignment of the shading film and the display areas. When more display areas exist on the LCD panel and the shapes of the shading areas are complicated, it is difficult to realize the accurate alignment of the shading film and the display areas of the LCD panel. Therefore, the preset aligning marks can be used for realizing the accurate alignment, simplifying an aligning process, and ensuring the aligning accuracy.

Preferably, the shading film is made of a metal material. This is a specific material of the shading film.

Preferably, the shading film is made of a resin material. This is another specific material of the shading film.

Preferably, the mask is made of glass or plastic cement. This is a specific material of the mask.

A method of production of a mask used for producing an LCD panel comprises the following steps: setting an opaque area on a translucent panel according to the shape of display areas of an LCD panel; covering a shading film on the translucent panel; and eliminating the shading film outside the opaque area.

An LCD panel production method, comprises the following steps:

A: Laying a mask used for producing an LCD panel on an LCD panel, wherein the shape of a shading film of the mask used for producing the LCD panel is consistent with the shape of display areas formed by a sealant, and arranging the shading film in the position corresponding to an upper part of the display areas;

B: Irradiating the sealant of the LCD panel exposed outside the shading film using a light source.

Preferably, in step A, the position of the shading film corresponds to the positions of the display areas by disposing aligning marks on the mask and the LCD panel. When more display areas exist on the LCD panel and the shapes of the shading areas are complicated, it is difficult to realize the accurate alignment of the shading film and the display areas of the LCD panel. Therefore, the preset aligning marks can be used for realizing the accurate alignment, simplifying the aligning process, and ensuring the aligning accuracy.

Preferably, in step B, the sealant is solidified by irradiation of the light source.

Preferably, in step B, the light source is ultraviolet light. This is a specific form of the light source.

Preferably, the LCD panel comprises an array substrate and a color filter substrate. The sealant can be coated on the array substrate or the color filter substrate.

Studies have shown that the optical errors or mura having different shapes are produced because the guide layers in the display areas are disturbed by the irradiation of the ultraviolet light source prior to production of a tilt angle. Therefore, before the tilt angle is produced, if other parts in addition to the sealant in the display areas are well separated, the problem can be solved. When the LCD panel is processed, the shading film of the mask used for producing the LCD panel is used for shielding the display area. In this way, when the light source is adopted for irradiation, ultraviolet wavelength can pass through the area other than the shading film to achieve the desired effect of complete separation. The producing process of the sealant or other producing processes can be finished by the translucent area so as to enhance the product quality. The mask used for producing the LCD panel is manufactured by the mask production method of the LCD. It is more important to use the principle of a TFT substrate or CF substrate for producing the mask to shield the display areas on a transparent base material (such as glass and plastic cement). Therefore, the production equipment and the technology of the existing LCD panel can be used for producing the mask used for making the LCD panel, thereby reducing the production cost and effectively preventing the disturbance from the light source.

### BRIEF DESCRIPTION OF FIGURES

FIG. 1 is a schematic diagram of a mask used for producing an LCD panel;

FIG. 2 is a schematic diagram of processing an LCD panel and an LCD of the present invention;

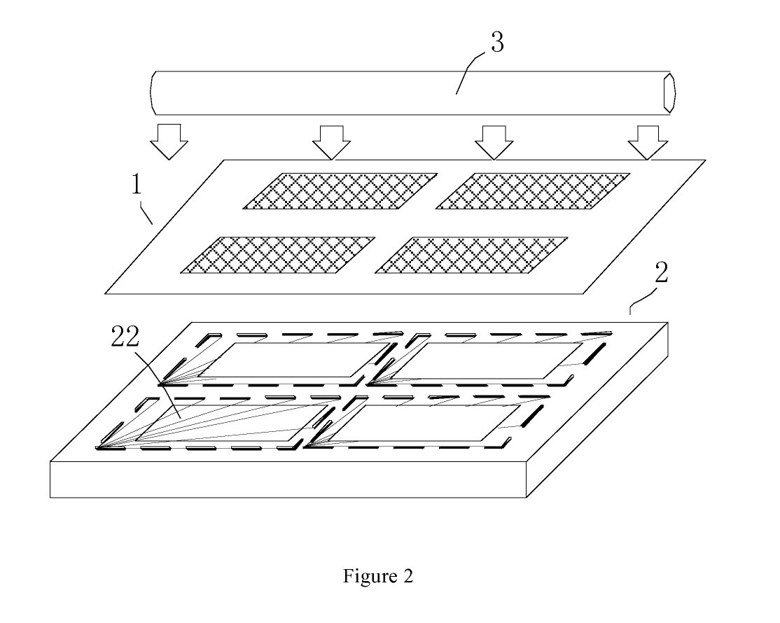

Wherein: 1. mask used for producing an LCD panel; 11. shading film; 12. aligning marks; 13. translucent panel; 2. LCD panel; 22. display areas; 3. ultraviolet light.

### DETAILED DESCRIPTION

The present invention will further be described in detail in accordance with the figures and the preferred embodiments.

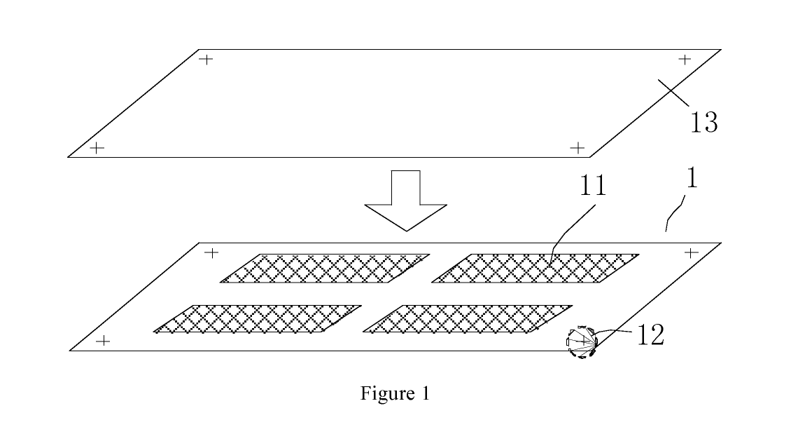

As shown in FIG. 1, a mask 1 used for producing an LCD panel comprises a translucent panel 13. A shading film 11 is covered on the translucent panel 13 and the shape of the shading film 11 is consistent with the shape of display areas 22 formed by a sealant coated on the LCD panel. The translucent panel 13 can be made of translucent materials including glass and plastic base materials; and the shading film 11 can be made of opaque materials including metal materials and resin materials.

Furthermore, the translucent panel 13 is further provided with aligning marks 12 used for conveniently realizing the accurate alignment of the shading film 11 and the display areas 22. When more display areas exist on the LCD panel and the shapes of the shading areas are complicated, it is difficult to realize the accurate alignment of the shading film 11 and the display areas of the LCD panel. Therefore, the preset aligning marks 12 can be used for realizing the accurate alignment. For example, aligning marks 12 in cross shapes are arranged in the four corner positions of the translucent panel 13. As long as the four aligning marks 12 are well positioned, the shading film 11 can be aligned well to the display areas of the LCD panel, which is convenient and reliable.

A production method of the mask 1 used for producing the LCD panel comprises the steps: setting an opaque area on the translucent panel 13 according to the shapes of the display areas of the LCD panel; covering the shading film 11 on the translucent panel 13; and eliminating the shading film 11 outside the opaque area. For example, the production principle of a TFT substrate or CF substrate can be used for eliminating the shading film 11 outside the opaque area by the technologies of exposure, etching, etc.

A method for production of an LCD panel 2 using the aforementioned mask comprises the following steps:

A: Laying the mask 1 used for producing the LCD panel on the LCD panel 2, wherein the shape of the shading film 11 of the mask 1 used for producing the LCD panel is consistent with the shape of the display areas 22 formed by the sealant; and arranging the shading film 11 in the position corresponding to an upper part of the display areas 22;

B: Irradiating the sealant of the LCD panel 2 exposed outside the shading film 11 using a light source. Ultraviolet light 3 can be adopted as a specific light source.

In step B, the position of the shading film 11 corresponds to the positions of the display areas 22 by disposing the aligning marks on the dedicated mask 1 and the LCD panel 2. When more display areas exist on the LCD panel 2 and the shapes of the shading areas are complicated, it is difficult to realize the accurate alignment of the shading film 11 and the display areas of the LCD panel 2. Therefore, the preset aligning marks 12 can be used for realizing the accurate alignment, simplifying the aligning process, and ensuring the aligning accuracy.

Furthermore, the LCD panel comprises an array substrate and a color filter substrate. The sealant can be coated on the array substrate or the color filter substrate.

The present invention is described in detail in accordance with the above contents with the specific preferred embodiments. However, this invention is not limited to the specific embodiments. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A mask used for producing a liquid crystal display (LCD) panel, comprising: a translucent panel, wherein said translucent panel is covered with a shading film and the shape of said shading film is consistent with the shape of display areas formed by a sealant coated on the LCD panel.

2. The mask used for producing the LCD panel of claim 1, wherein said translucent panel is further provided with aligning marks used for realizing the accurate alignment of the shading film and said display areas.

3. The mask used for producing the LCD panel of claim 1, wherein the shading film is made of a metal material.

4. The mask used for producing the LCD panel of claim 1, wherein the shading film is made of a resin material.

5. The mask used for producing the LCD panel of claim 1, wherein said mask is made of glass or a plastic material.

6. A method of production of a mask used for producing an LCD panel, comprising the following steps: setting an opaque area on a translucent panel according to the shape of display areas of the LCD panel; covering a shading film on the translucent panel; and eliminating the shading film outside the opaque area.

7. A method of production of an LCD panel, comprising the following steps:
A: laying a mask used for producing the LCD panel on the LCD panel, wherein the shape of a shading film of the mask used for producing the LCD panel is consistent with the shape of display areas formed by a sealant; arranging the shading film in the position corresponding to an upper part of the display areas;
B: irradiating the sealant of the LCD panel exposed outside the shading film using a light source.

8. The method of production of the LCD panel of claim 7, wherein in step A, the position of the shading film corresponds to the positions of the display areas by disposing aligning marks on the mask and the LCD panel.

9. The method of production of the LCD panel of claim 7, wherein in step B, the sealant is solidified by irradiation of the light source.

10. The method of production of the LCD panel of claim 7, wherein in step B, the light source is ultraviolet light.

11. The method of production of the LCD panel of claim 7, wherein the LCD panel respectively comprises an array substrate and a color filter substrate.
